(19) United States
(12) Patent Application Publication
(10) Pub. No.: US 2026/0214785 A1
(43) Pub. Date: Jul. 23, 2026

(54) CIRCUIT BOARD

(71) Applicant: LITE-ON TECHNOLOGY CORPORATION, TAIPEI CITY (TW)

(72) Inventor: Chuan-Yu Wang, TAIPEI CITY (TW)

(21) Appl. No.: 19/452,797

(22) Filed: Jan. 19, 2026

Related U.S. Application Data
(60) Provisional application No. 63/747,117, filed on Jan. 20, 2025.

(30) Foreign Application Priority Data
Jan. 15, 2026 (CN) 202620049125.1

(51) Int. Cl. H05K 1/02; H05K 1/181

(52) U.S. Cl. CPC H05K 1/0204; H05K 1/181; H05K 2201/0707; H05K 2201/10098

(57) ABSTRACT

A circuit board includes a substrate and a plurality of thermally conductive blocks. The substrate has a first surface layer and a second surface layer that are respectively disposed on two opposite sides of the substrate. A plurality of wireless circuit wiring regions that are separate from each other are disposed on the first surface layer. A chip mounting region is disposed in each of the wireless circuit wiring regions. The chip mounting region includes a heat dissipation region. The thermally conductive blocks are disposed in an interior of the substrate. Each of the thermally conductive blocks corresponds to one of the heat dissipation regions for dissipating heat of a power chip disposed in the chip mounting region.

### CROSS-REFERENCE TO RELATED PATENT APPLICATION

This application claims the benefit of priorities to the U.S. Provisional Patent Application Ser. No. 63/747,117, filed on Jan. 20, 2025, and China Patent Application No. 202620049125.1, filed on Jan. 15, 2026, in the People's Republic of China. The entire content of each of the above identified applications is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board, and more particularly to a circuit board for accommodation of multiple antennas.

### BACKGROUND OF THE DISCLOSURE

In order to meet the demand for high-speed and wireless transmission requirements, a number of wireless communication device products have been developed. For 5G wireless communication devices, a key component used in a 5G small cell is a radio-frequency power amplifier (RF PA). Such a power amplifier is usually implemented by a system on a chip (SoC), and is used to amplify a 5G high-frequency signal to the required power level and transmit the same via an antenna. When the 5G small cell outputs a radio-frequency signal, the power amplifier strives to maintain high performance, such that a direct current power is mostly converted into a signal output power.

Through effective digital pre-distortion (DPD) computation technologies, linear output characteristics of the power amplifier and compensation for non-linearities can be further realized, so as to enhance efficiency and an overall performance. However, due to such DPD computation technologies, a power conversion efficiency is approximately 40%, while heat thus generated is 60%. Furthermore, a quantity of antennas in the 5G small cell is increased. For example, in a multi-antenna framework of a currently mainstream multiple-input and multiple-output (MIMO) system, interference will occur at a transmission path of each antenna when multiple power amplifiers are simultaneously operated at a high power, thereby affecting characteristics of the power amplifier in improving an adjacent channel leakage ratio (ACLR) and an error vector magnitude (EVM).

### SUMMARY OF THE DISCLOSURE

In response to the above-referenced technical inadequacies, the present disclosure provides a circuit board.

In order to solve the above-mentioned problems, one of the technical aspects adopted by the present disclosure is to provide a circuit board, which includes a substrate and a plurality of thermally conductive blocks. The substrate has a first surface layer and a second surface layer. The first surface layer and the second surface layer are disposed on two opposite sides of the substrate. A plurality of wireless circuit wiring regions that are separate from each other are formed on the first surface layer. A chip mounting region is disposed in each of the wireless circuit wiring regions, and the chip mounting region includes a heat dissipation region. The thermally conductive blocks are disposed in an interior of the substrate. Each of the thermally conductive blocks corresponds to one of the heat dissipation regions, so as to dissipate heat of a power chip disposed in the chip mounting region.

Therefore, in the circuit board provided by the present disclosure, accumulation of heat sources and signal interference between the multiple power chips disposed on the circuit board can be effectively prevented, thereby enabling a wireless communication device using multi-antenna transmission to effectively enhance stability and efficiency of signal transmission.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a surface of a circuit board according to an embodiment of the present disclosure;

FIG. 2 is a schematic view showing power chips being disposed on the circuit board according to the embodiment of the present disclosure;

FIG. 3 is a schematic view of another surface of the circuit board according to the embodiment of the present disclosure;

FIG. 4 is a schematic cross-sectional view of a thermally conductive block in the circuit board according to the embodiment of the present disclosure; and

FIG. 5 is another schematic cross-sectional view of the thermally conductive block in the circuit board according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

One embodiment of the present disclosure provides a circuit board. Said circuit board can effectively dissipate high heat generated during operation of high-power components in a wireless communication device. In addition, multiple sets of antennas used in the wireless communication device are arranged to adopt a split-type circuit layout. Specifically, a thermally conductive channel is provided in an interior of the circuit board. Through the thermally conductive channel, high heat generated during operation of circuit components on one side of the circuit board is conducted to another side of the circuit board for heat dissipation, so as to effectively prevent heat sources from being excessively accumulated on the same side of the circuit board. For related circuits used in the multiple sets of antennas, the adopted split-type layout can prevent signal transmission paths used in the multiple sets of antennas from being adjacent to each other. Through such layout of the circuit board, accumulation of the heat sources and signal interference between the multiple sets of antennas in the wireless communication device can be reduced.

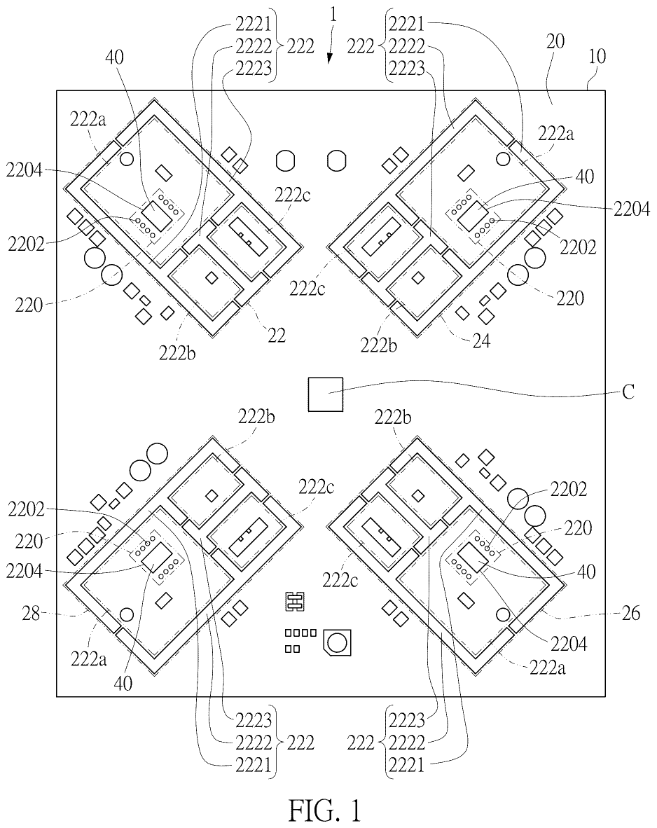

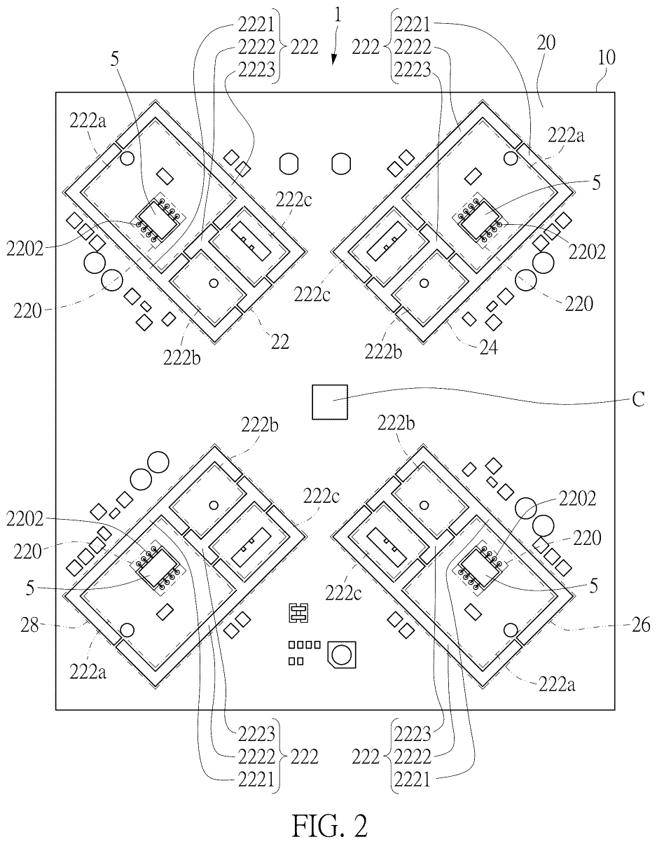

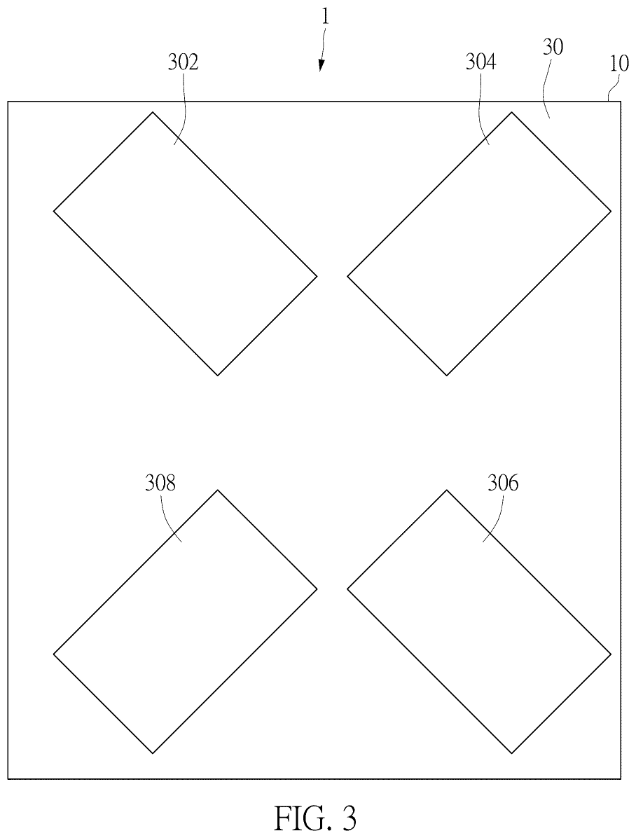

Reference is made to FIG. 1, FIG. 2, and FIG. 3. FIG. 1 is a schematic view of a surface of a circuit board according to an embodiment of the present disclosure. FIG. 2 is a schematic view showing power chips being disposed on the circuit board according to the embodiment of the present disclosure. FIG. 3 is a schematic view of another surface of the circuit board according to the embodiment of the present disclosure. In order to conveniently describe a framework of a circuit board 1, the circuit board 1 includes a substrate 10 and a plurality of thermally conductive blocks 40. One surface of the substrate 10 as shown in FIG. 1 is configured as a first surface layer 20, and another surface of the substrate 10 as shown in FIG. 3 is configured as a second surface layer 30. Specifically, the substrate 10 has the first surface layer 20 and the second surface layer 30 that correspond to each other in an up-and-down direction. The first surface layer 20 acts as a mounting surface for most circuit components. That is, the first surface layer 20 can be used as an upper layer of the substrate 10, and the second surface layer 30 can be used as a lower layer of the substrate 10. In other words, the first surface layer 20 and the second surface layer 30 are disposed on two opposite sides of the substrate 10, respectively.

It should be noted that a thermally conductive channel of the circuit board 1 is disposed between the first surface layer 20 and the second surface layer 30. Through the thermally conductive channel in an interior of the substrate 10, a heat source generated by a heating component of the first surface layer 20 is conducted to the second surface layer 30 for heat dissipation. A structural design of the thermally conductive channel will be described in detail below.

In one embodiment, the circuit components on the first surface layer 20 are divided into a plurality of split-type wireless circuit wiring regions according to a quantity of antennas that are installed. For example, when the quantity of the antennas is N, an N number of the wireless circuit wiring regions are disposed on the first surface layer 20 of the circuit board 1. Here, N is a positive integer greater than or equal to 2. The wireless circuit wiring region is provided for configuration of the circuit components that drive the antennas to transceive signals.

A framework in FIG. 1 is exemplified to include four antennas. As such, four split-type wireless circuit wiring regions are correspondingly disposed on the first surface layer 20 of the circuit board 1. Furthermore, these wireless circuit wiring regions are separately disposed to surround a periphery of the circuit board 1 with a reference position C of the circuit board 1 as a center of circle. For example, as shown in FIG. 1, a first wireless circuit wiring region 22 is disposed at an upper left corner of the circuit board 1, a second wireless circuit wiring region 24 is disposed at an upper right corner of the circuit board 1, a third wireless circuit wiring region 26 is disposed at a lower right corner of the circuit board 1, and a fourth wireless circuit wiring region 28 is disposed at a lower left corner of the circuit board 1.

It should be noted that a chip mounting region 220 is disposed in each wireless circuit wiring region. The chip mounting region 220 is provided for configuration of a power chip 5. The power chip 5 is, for example, a radio-frequency power amplifier (RF PA) used in the wireless communication device for driving the antennas to transmit the signals, or other power components that generate high heat due to operation. As shown in FIG. 2, the power chip 5 is disposed in the chip mounting region 220.

In one embodiment, the wireless circuit wiring regions are separate from each other. Specifically, the wireless circuit wiring regions are separately disposed to surround a periphery of the reference position C of the substrate 10, and any two adjacent ones of the chip mounting regions 220 form a same included angle with the reference position C as a center of circle. In addition, a distance between each chip mounting region 220 and the reference position C is the same. For example, in FIG. 1, there are four wireless circuit wiring regions. If mounting positions of the wireless circuit wiring regions are to be evenly arranged based on one circle, it can be observed that the included angle formed between any two adjacent ones of the chip mounting regions 220 based on the reference position C is 90 degrees.

In FIG. 1, the included angle between the chip mounting regions 220 of the first wireless circuit wiring region 22 and the second wireless circuit wiring region 24 is 90 degrees, the included angle between the chip mounting regions 220 of the second wireless circuit wiring region 24 and the third wireless circuit wiring region 26 is 90 degrees, the included angle between the chip mounting regions 220 of the third wireless circuit wiring region 26 and the fourth wireless circuit wiring region 28 is 90 degrees, and the included angle between the chip mounting regions 220 of the fourth wireless circuit wiring region 28 and the first wireless circuit wiring region 22 is 90 degrees. Through the above-mentioned configuration of the included angle, it can be ensured that a same distance is maintained between power chips in adjacent ones of the chip mounting regions 220, so as to prevent accumulation of the heat sources and the signal interference.

Similarly, in other embodiments, when the quantity of the antennas on the circuit board 1 is three, the wireless circuit wiring regions of the circuit board 1 is then three. That is to say, the included angle between any two of the chip mounting regions 220 based on the reference position C is 120 degrees. As such, in response to a different quantity of the antennas, a similar inference can be made (which will not be repeated herein).

In one embodiment, a position of the chip mounting region 220 can be away from the reference position C, and can be adjacent to a side of the substrate 10. For example, a minimum distance between the chip mounting region 220 and the side of the substrate 10 is less than the distance between the chip mounting region 220 and the reference position C, and the chip mounting regions 220 are equidistantly and maximally spaced apart from each other, thereby effectively reducing the signal interference therebetween. In this way, efficiency and stability of signal transmission can be enhanced.

In one embodiment, the chip mounting region 220 includes a pin region 2202 and a heat dissipation region 2204, and the pin region 2202 is disposed outside of the heat dissipation region 2204. For example, as shown in FIG. 2, when pins of the power chip 5 are disposed in the pin region 2202 of the chip mounting region 220, a bottom surface of the power chip 5 is adjacent to the heat dissipation region 2204.

In one embodiment, each wireless circuit wiring region further includes a shield region 222, and a metal shield member is disposed in the shield region 222 for shielding an interference signal generated between the antennas on the substrate 10, so as to ensure normal operation of the circuit components disposed in each wireless circuit wiring region. It should be noted that the wireless circuit wiring region can be subdivided according to different circuit functions. For example, the wireless circuit wiring region is further divided into a first circuit mounting region 222a, a second circuit mounting region 222b, and a third circuit mounting region 222c. Primary power chips and related circuit components are disposed in the first circuit mounting region 222a, secondary power chips and related circuit components are disposed in the second circuit mounting region 222b, and a filter and related circuit components are disposed in the third circuit mounting region 222c.

The shield region 222 can cooperate with each of the above-mentioned circuit mounting regions to perform shielding. For example, the shield region 222 can be further divided into a first shield mounting region 2221, a second shield mounting region 2222, and a third shield mounting region 2223. The first shield mounting region 2221, the second shield mounting region 2222, and the third shield mounting region 2223 are disposed to surround an outer periphery of the first circuit mounting region 222a. The first shield mounting region 2221 and the third shield mounting region 2223 are disposed to surround an outer periphery of the second circuit mounting region 222b. The second shield mounting region 2222 and the third shield mounting region 2223 are disposed to surround an outer periphery of the third circuit mounting region 222c. Furthermore, at the outer periphery of each circuit mounting region, a gap is formed between two adjacent ones of the shield mounting regions, and is used for wiring of the circuit components in each circuit mounting region.

It should be noted that the thermally conductive channel used in the substrate 10 is formed by disposing the thermally conductive blocks 40 within the substrate 10. That is, the heat dissipation region 2204 of each wireless circuit wiring region includes a corresponding one of the thermally conductive blocks 40. The thermally conductive block 40 mentioned herein can be a metal block, such as a copper block having excellent electrical and thermal conductivity. Specifically, in the substrate 10, the thermally conductive blocks 40 are disposed in a plurality of accommodating grooves that penetrate through the first surface layer 20 and the second surface layer 30, and the thermally conductive blocks 40 can conduct a heat source of the power chip 5 on the first surface layer 20 to the second surface layer 30.

In order to effectively enhance a heat dissipation effect, a plurality of thermally conductive diffusion layers are disposed on the second surface layer 30 (as shown in FIG. 3), and a quantity of the thermally conductive diffusion layers is the same as that of the wireless circuit wiring regions. In one embodiment, a mounting position of the thermally conductive diffusion layer corresponds to the mounting position of the wireless circuit wiring region. For example, as shown in FIG. 3, a first thermally conductive diffusion layer 302 corresponds to the first wireless circuit wiring region 22, a second thermally conductive diffusion layer 304 corresponds to the second wireless circuit wiring region 24, a third thermally conductive diffusion layer 306 corresponds to the third wireless circuit wiring region 26, and a fourth thermally conductive diffusion layer 308 corresponds to the fourth wireless circuit wiring region 28. Each thermally conductive diffusion layer in FIG. 3 is in contact with the thermally conductive block 40, and a mounting area of each thermally conductive diffusion layer is greater than the chip mounting region 220.

It can be understood that, when the thermally conductive block 40 conducts the heat source to the second surface layer 30, the heat source is dissipated through a large area of the thermally conductive diffusion layer. Accordingly, a heat dissipation efficiency can be greatly enhanced.

In one embodiment, the thermally conductive diffusion layer disposed on the second surface layer 30 can be a copper foil layer.

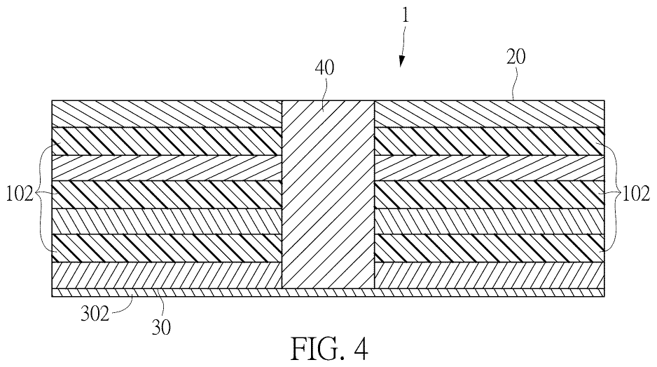

Referring to FIG. 4, FIG. 4 is a schematic cross-sectional view of a thermally conductive block in the circuit board according to the embodiment of the present disclosure. In FIG. 4, a thickness of the thermally conductive block 40 is exemplified to be the same as a thickness of the substrate 10. That is, the thermally conductive block 40 is flush with planar surfaces of the first surface layer 20 and the second surface layer 30 of the substrate 10, such that the thermally conductive block 40 in the heat dissipation region 2204 of the chip mounting region 220 can be in contact with the power chip 5 and dissipate its heat.

It should be noted that, while the heat source of the power chip 5 is conducted to the second surface layer 30 of the substrate 10 by the thermally conductive block 40 and heat dissipation is accelerated by the first thermally conductive diffusion layer 302 of the second surface layer 30, the substrate 10 is a multi-layer board. That is, the substrate 10 further includes other medium layers between the first surface layer 20 and the second surface layer 30 for transmission of different signals. The thermally conductive block 40 is in further contact with metal layers of the medium layers. Specifically, the thermally conductive block 40 can be in contact with one or more grounded metal layers 102 in the interior of the substrate 10. In other words, the thermally conductive block 40 can further conduct the heat source to the grounded metal layers 102 in the interior of the substrate 10, so as to enhance the heat dissipation efficiency. Similarly, other thermally conductive blocks 40 that correspond to different wireless circuit wiring regions also perform heat dissipation via such a framework.

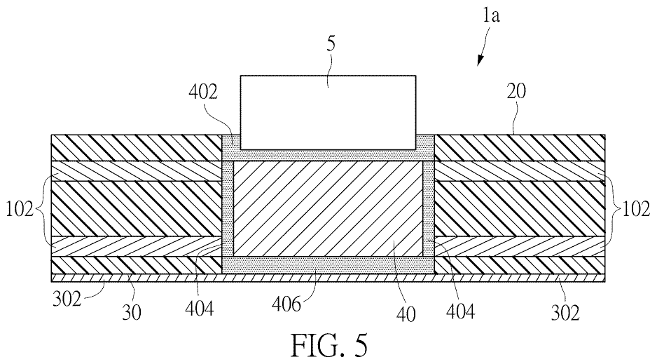

Referring to FIG. 5, FIG. 5 is another schematic cross-sectional view of the thermally conductive block in the circuit board according to the embodiment of the present disclosure. In FIG. 5, the thickness of the thermally conductive block 40 is exemplified to be less than the thickness of the substrate 10. That is, when the thermally conductive block 40 is disposed in the substrate 10, the thermally conductive block 40 can further contact an inner side wall of the substrate 10, the first surface layer 20, and the second surface layer 30 via different adhesive layers.

Specifically, as shown in FIG. 5, a first adhesive layer 402 is further disposed between the thermally conductive block 40 in a circuit board 1a and the power chip 5 in the heat dissipation region 2204, and the heat source of the power chip 5 is conducted to the thermally conductive block 40 via the first adhesive layer 402. A second adhesive layer 404 is further disposed between the thermally conductive block 40 and the inner side wall of the substrate 10, and the thermally conductive block 40 conducts the heat source to the grounded metal layers 102 in the substrate 10 via the second adhesive layer 404. A third adhesive layer 406 is further disposed between the thermally conductive block 40 and the first thermally conductive diffusion layer 302, and the thermally conductive block 40 conducts the heat source to the first thermally conductive diffusion layer 302 via the third adhesive layer 406. Similarly, other thermally conductive blocks 40 that correspond to different wireless circuit wiring regions also perform heat dissipation via such a framework.

As such, the heat source of the power chip 5 that is disposed at a side of the heat dissipation region 2204 can be conducted to the thermally conductive block 40 via the first adhesive layer 402, and the thermally conductive block 40 further conducts the heat source to the grounded metal layers 102 in the interior of the substrate 10 via the second adhesive layer 404. At the same time, the thermally conductive block 40 can also conduct the heat source to each thermally conductive diffusion layer of the second surface layer 30. Through different heat dissipation channels mentioned above, the thermally conductive block 40 can properly and effectively conduct the heat source of the power chip 5 that is disposed on the first surface layer 20 to the interior of the substrate 10 and the second surface layer 30 for heat dissipation.

In one embodiment, the first adhesive layer 402 is a solder paste layer, and the second adhesive layer 404 and the third adhesive layer 406 are each a copper paste layer.

### Beneficial Effects of the Embodiment

In conclusion, in the circuit board provided by the present disclosure, the power chips in the wireless communication device are arranged to be equidistantly spaced apart from each other according to the circuit layout of the circuit board. Through the thermally conductive blocks disposed in the circuit board, the heat sources of the power chips on one side of the circuit board can be effectively conducted to another side of the circuit board. Accordingly, accumulation of the heat sources and signal interference between the multiple power chips disposed on the circuit board can be effectively prevented, thereby enabling the wireless communication device using multi-antenna transmission to effectively enhance the stability and efficiency of signal transmission.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit board, comprising:
a substrate having a first surface layer and a second surface layer, wherein the first surface layer and the second surface layer are disposed on two opposite sides of the substrate, a plurality of wireless circuit wiring regions that are separate from each other are formed on the first surface layer, a chip mounting region is disposed in each of the plurality of wireless circuit wiring regions, and the chip mounting region includes a heat dissipation region; and
a plurality of thermally conductive blocks, wherein each of the plurality of thermally conductive blocks is disposed in an interior of the substrate, and corresponds to one of the heat dissipation regions, so as to dissipate heat of a power chip disposed in the chip mounting region.

2. The circuit board according to claim 1, wherein the plurality of wireless circuit wiring regions are disposed to surround a periphery of a reference position of the substrate, and any two adjacent ones of the chip mounting regions form a same included angle with the reference position as a center of circle.

3. The circuit board according to claim 2, wherein a distance between each of the chip mounting regions and the reference position is the same.

4. The circuit board according to claim 3, wherein a minimum distance between the chip mounting region and a side of the substrate is less than the distance between the chip mounting region and the reference position.

5. The circuit board according to claim 1, wherein a thermally conductive diffusion layer is disposed at a position where the second surface layer is in contact with each of the plurality of thermally conductive blocks.

6. The circuit board according to claim 5, wherein a mounting area of the thermally conductive diffusion layer is greater than the chip mounting region.

7. The circuit board according to claim 5, wherein a mounting position of the thermally conductive diffusion layer corresponds to the wireless circuit wiring region.

8. The circuit board according to claim 5, wherein the thermally conductive diffusion layer is a copper foil layer.

9. The circuit board according to claim 1, wherein the wireless circuit wiring region further includes a shield region, and a metal shield member is disposed in the shield region for shielding an interference signal generated on the substrate.

10. The circuit board according to claim 5, wherein the substrate is a multi-layer board, and the thermally conductive block is in contact with one or more grounded metal layers in the multi-layer board.

11. The circuit board according to claim 1, wherein a thickness of the thermally conductive block is less than or equal to a thickness of the substrate.

12. The circuit board according to claim 1, wherein the thermally conductive block is a copper block.

13. The circuit board according to claim 10, wherein a first adhesive layer is further disposed between the thermally conductive block and the power chip in the heat dissipation region, and a heat source of the power chip is conducted to the thermally conductive block via the first adhesive layer.

14. The circuit board according to claim 13, wherein the first adhesive layer is a solder paste layer.

15. The circuit board according to claim 14, wherein a second adhesive layer is further disposed between the thermally conductive block and an inner side wall of the substrate, and the thermally conductive block conducts the heat source to the grounded metal layers via the second adhesive layer.

16. The circuit board according to claim 15, wherein a third adhesive layer is further disposed between the thermally conductive block and the thermally conductive diffusion layer, and the thermally conductive block conducts the heat source to the thermally conductive diffusion layer via the third adhesive layer.

17. The circuit board according to claim 16, wherein the second adhesive layer and the third adhesive layer are each a copper paste layer.

18. The circuit board according to claim 1, wherein the chip mounting region further includes a pin region, and the pin region is disposed outside of the heat dissipation region.
